(19) United States
(12) Patent Application Publication
(10) Pub. No.: US 2003/0112606 A1
(43) Pub. Date: Jun. 19, 2003

(54) Push-in card

(76) Inventor: Andreas Burghart, Konigsbrunn (DE)

Correspondence Address: NEIFELD IP LAW, PC, 2001 JEFFERSON DAVIS HIGHWAY, ARLINGTON, VA, 22202, US

(21) Appl. No.: 10/240,044

(22) PCT Filed: May 17, 2002
(86) PCT No.: PCT/DE02/01785

(30) Foreign Application Priority Data
May 30, 2001 (DE) 10126330.9

(51) Int. Cl. H05K 1/14

(52) U.S. Cl. 361/736

(57) ABSTRACT

The invention relates to a push-in card with an attachment device (1), which is arranged on a side edge of the printed circuit board (2), with a first and a second attachment element (3, 4), the first attachment element (3) being attached to the printed circuit board and the second attachment element (4) being attachable by an attachment means (6) to a housing (10), in which the push-in card is received. The push-in card according to the invention is characterized in that the first and second attachment elements are connected to each other either movably, pluggably or integrally with an additional predetermined breaking point.

The invention relates to a push-in card with a printed circuit board and an attachment device, which is arranged on a side edge of the printed circuit board, with a first and at least a second attachment element, the first attachment element being attached to the printed circuit board and the second attachment element being attachable by an attachment means to a housing, in which the push-in card is received.

Push-in cards of this type are provided in many electronic devices, in particular in computers. The push-in cards are, for example, interface cards, modems or sound cards. Contacts are provided on one side of the printed circuit board, so that the printed circuit board can be pushed into a corresponding edge connector. As this happens, an electrical and mechanical contact is produced between the push-in card and a main board, which carries the edge connector.

The attachment device is generally formed as a metal rail, an angle piece being provided at one end of the rail to allow the attachment rail to be attached to a housing in which the push-in card is received. This attachment rail is arranged on a second edge of the printed circuit board, which is perpendicular to the edge carrying the contacts. The second attachment element, in the form of the angle, is to be provided to achieve adequate mechanical stability, since receptacles for the connection of cables are often provided on the attachment device. During plugging in and unplugging, mechanical forces occur, forces which cannot be absorbed alone by the clamping action of the plug-in device for the electrical connection of the printed circuit board to the main board. Moreover, there is the risk of the force effect causing the printed circuit board to slip completely or partly out of the plug-in device. Furthermore, it can be ensured by means of the attachment device that the push-in card is completely inserted and consequently that there is a reliable contact at all contact points.

The computer housings are in many cases made to match the size of the push-in cards. A certain standard size has been developed in this respect, so that push-in cards can be used in all standard housings. However, continuing development of semiconductor technology has over time reduced the size of the push-in cards, so that it is now possible also to use smaller housings. Consequently, a second standard has been developed for smaller push-in cards. It is problematical in the case of the push-in cards of the type stated at the beginning that they are only suitable for one standard size, although the size of the printed circuit board is the same in both cases. To adapt to the larger standard, the attachment elements are simply made longer. However, the use of push-in cards of the same function with different sizes is expensive, since additional costs are incurred in production, transport and storage. In addition, problems arise in the possible event of components being exchanged, because the replacement component not only has to have the corresponding function but also the corresponding size.

It is therefore an object of the invention to specify a push-in card which can be used for different sizes of housing.

This object is achieved by a push-in card of the type stated at the beginning which is characterized in that the first and second attachment elements are movably connected to each other. Similarly, the task is achieved by a push-in card of the type stated at the beginning in which the first and second attachment elements can be connected to each other by a plug-in and/or clamping connection, or by a push-in card in which the first and second attachment elements are integrally connected to each other and can be separated at a predetermined breaking point.

These solutions are based on the common idea of the invention that the attachment device is not rigid but is designed in a two-part form in such a way that different lengths of the attachment device can be realized.

According to the first solution, the attachment elements are movably connected to each other, preferably by means of a hinge. The hinge is in this case arranged in such a way that, in the case of the second attachment element, a long portion and a short portion are formed, the short portion being used in the case of a small housing to attach the attachment device to the housing by an attachment means and the long portion being correspondingly used in the case of a large housing.

According to the second solution, the two attachment elements are connected to each other in a pluggable way, the manner in which they are plugged together allowing different lengths of the attachment device to be realized.

In a third solution, the two attachment elements are integrally connected to each other, a predetermined breaking point being provided for separating them. In the case of a large housing, the attachment device is used in such a way that the two attachment elements are connected to each other. If, however, the push-in card is to be inserted into a small housing, the two attachment elements can be separated from each other by a relatively small force and, by plugging together, can be connected again in such a way that the attachment device can then be used in a small housing.

What is advantageous about these arrangements is that they can all be realized without great expenditure, and consequently only low additional costs are incurred. Nevertheless, the advantage that it is now only necessary for one push-in card to be provided for different sizes is obtained.

The invention is explained in more detail below on the basis of exemplary embodiments, in which:

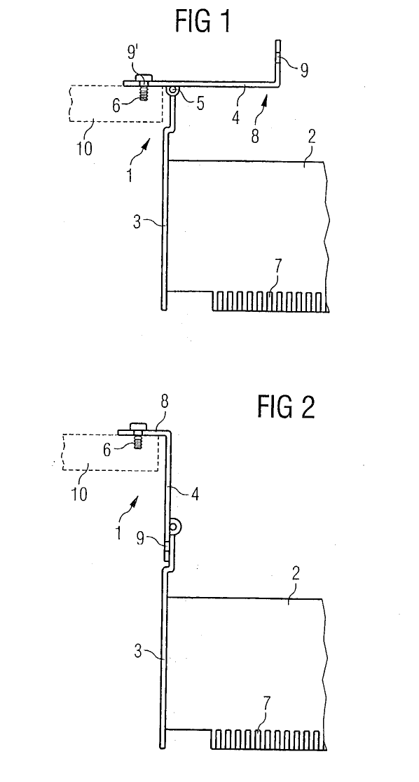

FIGS. 1 and 2 show a first exemplary embodiment of the invention,

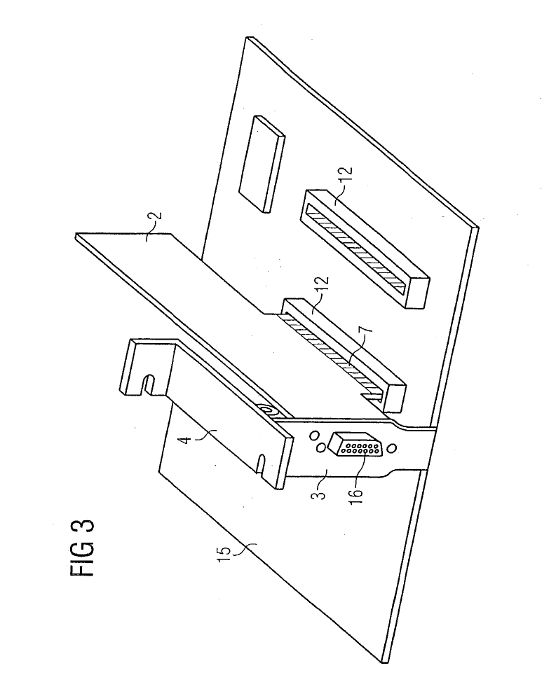

FIG. 3 shows a push-in card according to FIGS. 1 and 2 in a three-dimensional view,

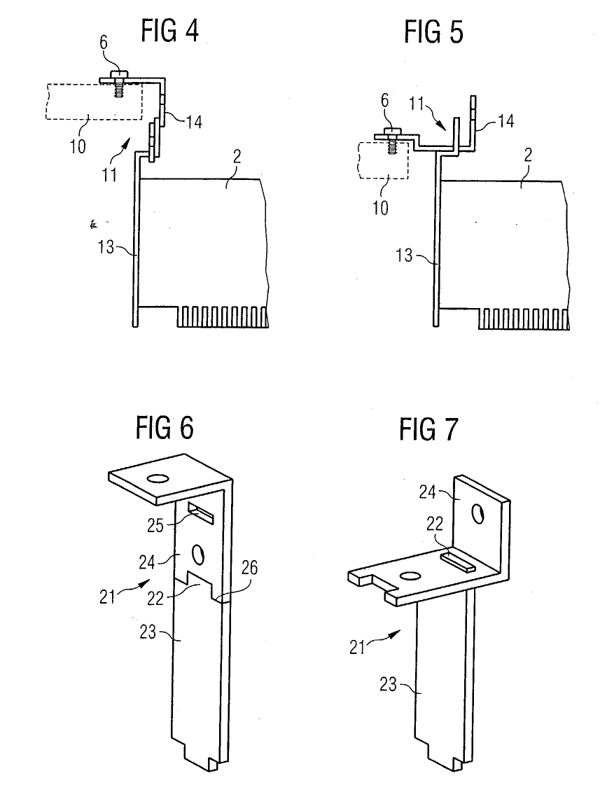

FIGS. 4 and 5 show a second exemplary embodiment of a push-in card according to the invention and

FIGS. 6 and 7 show a third exemplary embodiment of a push-in card according to the invention.

In the first exemplary embodiment according to FIGS. 1 and 2, a printed circuit board 2 is provided with an attachment device 1. The latter is arranged on an edge of the printed circuit board 2. Perpendicular to this edge there is an edge with contact areas 7 for the connection of the printed circuit board by means of a plug-in device to a main board, which is not represented in FIGS. 1 and 2 (cf. FIG. 3). The connection between the attachment device 1 and the printed circuit board 2 takes place at a first attachment element 3 The latter extends beyond the printed circuit board 2 and is connected at the end extending beyond the printed circuit board 2 to a second attachment element 4 by means of a hinge 5. The hinge divides the second attachment element 4 into two legs, the short leg having a bore for an attachment means 6 in the form of, for example, a screw. The long leg 4 has an angular end piece 8.

In the representation of FIG. 1, the second attachment element 4 has been pivoted into a position perpendicular to the first attachment element 3. In the position represented, the attachment element 1 can then be attached to a housing element 10 by means of a screw 6.

In FIG. 2, the arrangement of FIG. 1 is represented, although in this representation the second attachment element 4 has been pivoted in such a way that it forms a continuation of the first attachment element 3. While in the representation of FIG. 1 an angle is formed by the second attachment element 4 lying perpendicular to the first attachment element 3, in FIG. 2 the angle is produced by the one end of the second attachment element 4 being formed as an angle piece 8. However, in FIG. 2, the distance between the angle piece 8 and the edge with the contacts 7 is much greater than the distance between the point of attachment and the contact area 7 in the representation of FIG. 1. In the case of the use according to FIG. 1, the push-in card is suitable for housings conforming to the “small” standard, in the case of the use according to FIG. 3 it is suitable for housings conforming to the “large” standard. In both figures, part of the housing 10 to which the attachment device 1 can be fixed by the attachment means 6 is indicated by dashed lines.

In FIG. 3, a three-dimensional representation of the arrangement of FIGS. 1 and 2 is shown. The printed circuit board 2 of the push-in card has been received with the contacts 7 in an edge connector 12 on a main board 15. On the first attachment element 3 there is provided a receptacle 16, into which, for example, a printer cable can be inserted. The forces occurring during the insertion are absorbed by an attachment of the second attachment element 4 to a housing part, the housing not being represented for the sake of the overall clarity of the representation. However, the attachment takes place in the way shown in FIGS. 1 and 2.

In a second exemplary embodiment according to FIGS. 4 and 5, an attachment device 11 is made up of two attachment elements 13 and 14, the two attachment elements 13 and 14 being able to be connected to each other by plugging. In this case, too, the second attachment element 14 is designed substantially in an angular form, the long leg of the angle lying parallel to the longitudinal extent of the first attachment element 13, and connected to it by plugging, in the case of a large housing, and the long leg of the angle standing perpendicularly on the attachment element 13 in the case of a small housing. In this case, the attachment takes place with the screw 6 to the long leg, whereas in the case of the large housing the screw 6 is used on the short leg.

In a third exemplary embodiment according to FIGS. 6 and 7, attachment elements 23 and 24 of the attachment device 21 are at first integrally connected to each other. However, between the attachment elements 23 and 24 there is a predetermined breaking point 26, at which the two attachment elements 23 and 24 can be separated. In the original integral state, the attachment device 21 is suitable for a large housing. If, however, a small housing is to be used, the attachment device 21 can be separated into two parts at the predetermined breaking point 26. Such a predetermined breaking point can be subjected to relatively great tensile loading, so that there is adequate stability in normal use. Only when flexural loading is applied can breaking be accomplished at this point by exerting relatively little force.

A lug 22 remains on the first attachment element 23. A clearance 25, the size of which is made to match the lug 22, is provided on the second attachment element 24. After the separation of the attachment elements 23 and 24, the two attachment elements can therefore be connected to each other again by plugging. As also in the first two exemplary embodiments of FIGS. 1 to 3 and 4 and 5, respectively, this produces a shortened attachment device, an angle which can be used for attachment to a housing element 10 being formed both in the long variant and in the short variant.

The configuration of FIGS. 6 and 7 has the advantage that it can be realized particularly easily. The only disadvantage is that breaking at the predetermined breaking point 26 is irreversible, with the result that the push-in card which has such an attachment device 21 cannot subsequently be used again in a large housing without the attachment device 21 being renewed.

List of Designations

1 attachment device

2 printed circuit board

3 first attachment element

4 second attachment element

5 hinge

6 attachment means

7 contacts

8 angle piece

9 bore

10 housing element

11 attachment device

12 edge connector

13 first attachment element

14 second attachment element

15 main board

16 receptacle

21 attachment device

22 lug

23 first attachment element

24 second attachment element

25 clearance

26 predetermined breaking point

1. Push-in card with a printed circuit board (2) and an attachment device (1; 11; 21), which is arranged on a side edge of the printed circuit board (2), with a first and at least a second attachment element (3, 4; 13, 14; 23, 24), the first attachment element (3; 13; 24) being attached to the printed circuit board (2) and the second attachment element (4; 14; 24) being attachable by an attachment means (6) to a housing (10), in which the push-in card is received, characterized in that the first and second attachment elements (3, 4) are movably connected to each other.

2. Push-in card according to claim 1, characterized in that the first and second attachment elements (3, 4) are pivotably connected to each other by a hinge.

3. Push-in card with a printed circuit board (2) and an attachment device (1; 11; 21), which is arranged on a side edge of the printed circuit board (2), with a first and at least a second attachment element (3, 4; 13, 14; 23, 24), the first attachment element (3; 13; 24) being attached to the printed circuit board (2) and the second attachment element (4; 14; 24) being attachable by an attachment means (6) to a housing (10), in which the push-in card is received, characterized in that the first and second attachment elements (13, 14) can be connected to each other by a plug-in and/or clamping connection.

4. Push-in card with a printed circuit board (2) and an attachment device (1; 11; 21), which is arranged on a side edge of the printed circuit board (2), with a first and at least a second attachment element (3, 4; 13, 14; 23, 24), the first attachment element (3; 13; 24) being attached to the printed circuit board (2) and the second attachment element (4; 14; 24) being attachable by an attachment means (6) to a housing (10), in which the push-in card is received, characterized in that the first and second attachment elements (23, 24) are integrally connected to each other and can be separated at a predetermined breaking point (26).

5. Push-in card according to claim 4, characterized in that an additional plug-in possibility (22, 25) is provided for the connection of first and second attachment elements (23, 24) that are separated from each other.
